(19) United States
(12) Patent Application Publication
(10) Pub. No.: US 2022/0032530 A1
(43) Pub. Date: Feb. 3, 2022

(54) CURVED FUNCTIONAL FILM STRUCTURE AND METHOD FOR PRODUCING SAME

(71) Applicants: Joanneum Research Forschungsgesellschaft mbH, Graz (AT); Hueck Folien GmbH, Baumgartenberg (AT); Scio Holding GmbH, Linz (AT)

(72) Inventors: Barbara Stadlober, Graz (AT); Maria Belegratis, Pischelsdorf am Kulm (AT); Volker Schmidt, Pischelsdorf am Kulm (AT); Martin Zirkl, Ludersdorf-Wilfersdorf (AT); Gregor Scheipl, Graz (AT); Stephan Trassl, Baugartenberg (AT); Andreas Gschwandtner, Linz (AT); Franz Padinger, St. Marien (AT); Michael Heilmann, Weisskirchen/Traun (AT); Dirk Ide, Linz (AT)

(73) Assignees: Joanneum Research Forschungsgesellschaft mbH, Graz (AT); Hueck Folien GmbH, Baumgartenberg (AT); Scio Holding GmbH, Linz (AT)

(21) Appl. No.: 17/312,410

(22) PCT Filed: Dec. 10, 2019
(86) PCT No.: PCT/EP2019/084345

§ 371 Date: Jun. 10, 2021

(30) Foreign Application Priority Data
Dec. 11, 2018 (DE) 10 2018 131 760.3

(51) Int. Cl. B29C 51/08; H05K 1/18; H05K 3/00; H05K 3/46; H05K 3/30; B29C 51/14; G01L 9/00; G01K 7/16

(52) U.S. Cl. CPC B29C 51/08; H05K 1/18; H05K 3/0011; H05K 3/4644; H05K 3/305; B29L 2031/3406; G01L 9/0041; G01K 7/16; H05K 2201/10151; H05K 2201/10106; B29C 51/14

(57) ABSTRACT

The present invention provides a functional film structure and a method of manufacturing the same. The functional film structure has a sensor button arranged on a film substrate and can be formed into a three-dimensional shape by thermal forming processes such as vacuum deep-drawing or high-pressure moulding. The functional film structure is preferably flexible and preferably has transparent and illuminated sections.

### FIELD OF THE INVENTION

The present invention relates to a three-dimensionally shaped functional film structure with a sensor unit and a method of manufacturing the same.

### STATE OF THE ART

Currently, film surfaces are often provided with functions in the field of structural electronics, in-mold electronics and three-dimensional (3D) integrated electronics. The functional films are then formed into a three-dimensional shape or backmoulded in a Foil Insertion Moulding process (FIM) and thus mechanically stabilised. Examples of this are the European project TERASEL1, in which several FIM demonstrators were provided, such as the 3D integration of LEDs on a three-dimensional plastic calotte or a plate with homogeneously illuminated recesses based on integrated LEDs. There is also a back-moulded LED display or a luminous flexible wristband on the market, where the LEDs are first placed on stretchable substrates using pick-and-place and then slightly deformed. This is followed by overmoulding and stabilisation in an injection moulding process using the roll-to-roll (R2R) process. The companies Taktotek and plastic electronic are also working on smart 3D integrated electronics, in both cases proposing smart surfaces such as operating household appliances, white goods, automotive interiors and wearables. Here, various capacitive switches and sliders are integrated on flat film substrates, then formed and stabilised by means of injection moulding.

### PROBLEMS TO BE SOLVED BY THE INVENTION

However, the prior art does not disclose a structure in which pressure- or temperature-sensitive buttons have been made into a three-dimensional shape.

Therefore, it is the object of the present invention to provide a structure in which functionalities such as optical, electrical and/or sensory functionalities are applied to a three-dimensionally shaped and preferably flexible film substrate.

Further objects of the invention are to produce a transparent, flexible sensor button on a film substrate with the following properties: (i) pressure or temperature sensitivity of the sensor button, (ii) partial transparency for illumination or backlighting of the button by either LEDs mounted next to the sensor or waveguides for light distribution of remote LEDs, (iii) deformability of the assembled and printed substrate by thermal forming processes such as vacuum deep-drawing or high-pressure forming.

### SUMMARY OF THE INVENTION

The object was accomplished by providing a functional film structure having a sensor button arranged on a film substrate, wherein the functional film structure is formed into a three-dimensional shape by thermal forming processes such as vacuum deep-drawing or high-pressure forming.

More particularly, the object of the present invention is defined in the following points [1] to [15]:
[1] A functional film structure having a curvature and being obtainable by a process comprising the steps of:
   (a) providing a functional film comprising a film substrate and a sensor unit disposed thereon, the sensor unit having a sensor and a conductor connected thereto, the sensor responding to at least one change selected from pressure and temperature change; and
   (b) forming the curvature in the functional film in a section at least partially comprising the sensor and the conductor, thereby stretching the conductor and the sensor.

The curvature of the functional film structure according to the invention thus comprises at least a part of the sensor and a part of the conductor, the part of the sensor and the part of the conductor being stretched. Preferably, the sensor is fully contained in the curved section.
[2] The functional film structure of point [1], wherein the sensor is a layered sensor comprising, in the indicated order, a first electrically conductive layer, a layer of a ferroelectric polymer and a second electrically conductive layer.

In a preferred embodiment according to point [2], the sensor is fully contained in the curved section and is curved from the x-y-plane in z-direction by at least 3 mm.
[3] The functional film structure according to point [1] or [2], wherein the ferroelectric polymer layer, the electrically conductive layers and the conductor are printable.
[4] The functional film structure according to any one of the preceding points, wherein the section containing the sensor is thicker than the section adjacent thereto.

In a preferred structure according to point [1] and [4], the sensor is fully contained in the curved section and the section containing the sensor is at least 0.1 mm, preferably at least 0.3 mm thicker than the section adjacent thereto.
[5] The functional film structure according to any one of the preceding points, which is self-supporting.
[6] The functional film structure according to any one of the preceding points, wherein the curvature contains a section being stretched by at least 20% in comparison to the non-curved section.
[7] The functional film structure according to any one of the preceding points, wherein a component mounting structure comprising, in the indicated order, a conductive adhesive, electrical components and a lacquer is applied to the film substrate.
[8] The functional film structure according to point [7], comprising an adhesive film over the component mounting structure or the component mounting structure and the layer sensor for bonding to the film substrate.
[9] The functional film structure according to any one of the preceding points, comprising a light-emitting element that is coupled to the sensor via a waveguide such that it can cause the sensor to illuminate.
[10] A functional film structure having a functional film comprising a film substrate and a sensor unit disposed thereon, the sensor unit having a sensor and a conductor connected thereto, the sensor responding to at least one change selected from pressure and temperature change, wherein the functional film further comprises a curvature in a section at least partially comprising the sensor and the conductor, the conductor and the sensor being stretched. The functional film structure preferably shows the characterizing features according to any one of points [1] to [9].
[11] A method of manufacturing a functional film structure according to any one of the preceding points, comprising the steps of:

(a) providing a functional film comprising a film substrate and a sensor unit disposed thereon, the sensor unit having a sensor and a conductor connected thereto; and

(b) forming a curvature in the functional film in a section at least partially comprising the sensor and the conductor, thereby stretching the conductor and the sensor.
[12] The method of point [11], wherein step (a) comprises providing the film substrate, equipping the film substrate with the sensor, the conductor and other elements, and applying a film to the equipped film substrate to produce the functional film.
[13] The method according to point [11] or [12], wherein the sensor has a layered structure, the other elements comprise SMD components and the application of the film to the equipped film substrate is a thermal lamination with a hot-melt adhesive film.
[14] The method according to point [12] or [13], wherein the production of the layer structure of the sensor is carried out by means of screen printing or engraving printing with intermediate baking steps and/or the conductor is applied by means of screen printing and a subsequent baking step.
[15] The process according to any one of points [11] to [14], wherein step (b) is performed by a high-pressure forming process or deep-drawing process against a suitable tool.

### ADVANTAGES OF THE INVENTION

The functional film structure according to the invention has a sensor in a curved structure. Compared to a sensor in a planar structure, this design has the fundamental advantage that the sensor is exposed and thus its sensitivity can be increased or its size can be reduced, and a haptic structure supports the tactility of sensor elements. For example, a pressure sensor in the exposed curved structure is more sensitive to pressure than a pressure sensor in a planar surface, where the pressure load is partially dissipated onto the entire surface and thereby distributed. In addition, the total surface area is increased in a curved structure so that the area of the sensor and thus its sensitivity can be increased.

The functional film structure according to the invention is suitable for use as a button or button array with a seamless surface in, for example, a control panel.

The structure according to the invention has a high pressure or temperature sensitivity of the sensor button, which reacts to different button pressure levels or to the approach of a person and generates a proportional electrical signal.

The membrane keypads used in the present invention have the usual advantages of membrane keypads, namely low susceptibility to soiling, high durability, rapid adaptation of the design and a cost-effective and easily controllable manufacturing process.

Further advantages are free design and free formability in the sense of a “function follows form” approach, any sensor shape, a flat and light sandwich construction, transparency as well as production by means of methods suitable for mass production such as screen printing, stencil printing and pick-and-place. Wire harnesses and complicated assembly of components and functional units are avoided. The advantages on the manufacturer's side are therefore a reduction in costs due to simpler production and assembly and a better environmental balance due to shortened delivery routes. For the user, intuitive operation, lower volume and weight, elegant design and easy cleaning of the seamless user interface are advantages.

The structure according to the invention has a high formability of the assembled and printed substrate by thermal forming processes such as vacuum deep drawing or high-pressure moulding.

In a preferred embodiment, the structure according to the invention is partially transparent for illumination or backlighting of the button by either LEDs mounted next to the sensor or waveguides for light distribution of remote LEDs.

### DESCRIPTION OF THE FIGURES

FIG. 1 shows an embodiment of the present invention. In its manufacture, a functional sample of a backlit and three-dimensionally shaped pressure-sensitive sensor button with a seamless surface was produced, whereby the sensor button is first applied to a planar substrate using a suitable process and is then three-dimensionally shaped using a suitable process. All functionalities (optical, electrical, sensory) are first integrated on a single film substrate, and then the transfer into the three-dimensional shape takes place.

FIGS. 1a) and 1b) show the functional film structure before shaping; FIGS. 1c) and 1d) show the functional film structure after shaping, i.e. the functional film structure according to the invention.

FIG. 2 shows a schematic of a backlit pressure- or temperature-sensitive film sensor button that has a three-dimensional shape (e.g. console) and also has laminate, scatter layer/melt adhesive film and contour colour.

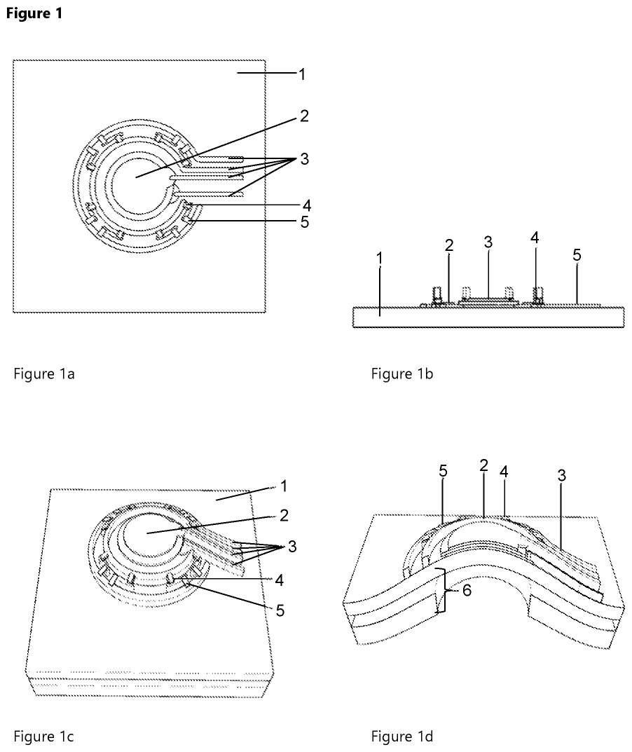

### EMBODIMENTS OF THE INVENTION

The functional film structure according to the invention comprises a film substrate and a sensor unit arranged thereon. In other words, the sensor unit is applied, preferably directly, to the surface of the film substrate.

The functional film structure according to the invention has one or more sensor units. It is thus used to measure changes in the environment. In the presence of several sensor units, these can measure different environmental properties. The sensor responds to at least one change in an environmental property selected from the group consisting of pressure, temperature, light intensity, humidity or gas concentration. Preferably, the sensor unit measures a pressure difference and/or temperature difference, more preferably both. This external stimulus is preferably converted into a proportional amount of charge.

Preferably, the sensor unit is integrated on the three-dimensionally deformed, continuous surface of the film substrate.

The sensor unit used in the present invention, which includes a sensor and a conductor connected thereto, is not limited as to the number of sensors and conductors. Rather, the sensor unit may comprise a plurality of sensors. Each of these sensors may have a plurality of conductors. Thus, the expressions “a sensor” and “a conductor” mean “at least one sensor” and “at least one conductor”, respectively. Correspondingly, the expressions “contains . . . a sensor” and “contains . . . a conductor” or analogous formulations are thus synonymous with “contains . . . at least one sensor” or “contains . . . at least one conductor”. This also applies correspondingly to the other elements of the functional film structure according to the invention, e.g. the curvature.

The conductor connected to the sensor can be any conductor. It can be an electrical conductor and be in the form of a conductor path. It can also be an optical conductor such as a waveguide for conducting light from an LED to a sensor.

The sensor in the functional film structure according to the invention preferably reacts to pressure differences between 5 g (5 mbar for an area of 1 cm²) and 1000 kg (1000 bar for an area of 1 cm²), more preferably 10 g to 100 kg, and/or to temperature differences of at least 0.1 K, more preferably at least 0.2 K and most preferably at least 0.5 K.

The functional film structure according to the invention has a flat structure of the film. That is, the length in the x-direction and the width in the y-direction are each preferably greater than the thickness in the z-direction by a factor of at least 10, more preferably at least 50, even more preferably at least 100. In the functional film structure, the elements, i.e. at least the film substrate and at least the sensor, preferably the entire sensor unit, preferably also have a flat structure according to the stated definition.

The functional film structure according to the invention has a total thickness of the functional film of preferably 20 μm to 10 mm, more preferably 50 μm to 5 mm, even more preferably 100 μm to 1 mm.

In preferred embodiments, the thickness of the film substrate is 20 to 1000 μm and the thickness of the sensor unit is 1 to 100 μm, more preferred is a combination of a thickness of the film substrate of 50 to 500 μm and a thickness of the sensor unit of 1 to 50 μm.

In a preferred embodiment, both the film substrate and the sensor unit are thermoplastically deformable. Thus, the entire functional film is thermoplastically deformable.

In one embodiment, the functional film structure in the section with sensor unit and conductor has the same thickness as the immediately adjacent section without sensor unit and conductor. In the transition section, the thicknesses are therefore the same throughout. They can deviate from each other by at most 10% or less than 50 μm, less than 20 μm or less than 10 μm. This makes it impossible to feel the section of the sensor unit.

In another embodiment, the functional film structure in the section with sensor unit has a different thickness than the immediately adjacent section without sensor unit. Preferably, the section with sensor unit is the section of the sensor, more preferably exclusively the section of the sensor, i.e. without the conductor or other adjacent structures. The thicknesses are therefore different in the transition section. The section with sensor can be thicker or thinner than the section without sensor. In both cases, the section of the sensor can thus be felt. The thicknesses can preferably differ by 1 to 2000 μm, more preferably 10 to 500 μm. Even more preferred are differences in the range of 50 to 1000 μm, 100 to 500 μm or 50 to 300 μm.

The term “functional film” refers to the functional film structure according to the invention before shaping, i.e. before forming the curvature.

The sensor, which responds to pressure differences and/or temperature differences, can for example respond to the touch of a finger of the user. Therefore, the sensor can also be called a switch, switching element or sensor button.

The functional film structure according to the invention is preferably flexible or preferably has flexible sections. In particular, it is preferred that the section around the sensor button is flexible so that it yields elastically when operated by the user, that is, when the button is pressed with a finger. Therefore, the section enclosing the sensor button should be flexible. This section is preferably at least partially, more preferably completely, in a curved section. The flexibility or resilience of the section should preferably be such that, at room temperature, when the sensor button, which is located centrally in a sample piece of the functional film structure of 3 cm×3 cm, is loaded vertically with an object having a mass of 100 g and a contact area of 1 cm² in the direction of loading, a deformation of at least 1 μm, more preferably at least 10 μm and even more preferably at least 50 μm occurs. Examples of preferred deformation ranges are selected from 1 to 1000 μm, 10 to 1000 μm, 50 to 1000 μm, 1 to 500 μm, 10 to 500 μm or 100 to 500 μm.

The functional film structure according to the invention is preferably self-supporting. This means that it is dimensionally stable at room temperature without a carrier. Preferably, it does not have a support. The functional film structure according to the invention is preferably self-supporting, i.e. without a carrier, and flexible or has flexible section. It is therefore two-dimensional and preferably self-supporting and flexible.

However, the functional film structure according to the invention can also have a carrier. The functional film can be applied to a carrier after shaping. In this way, the carrier structure can be precisely adapted to the functional film structure. Alternatively, the support may have a curvature, and step (b) of the method according to the invention may be a deformation of the functional film by applying it to the curved support. In this way, the functional film structure can be precisely adapted to the carrier structure.

During the deformation in step (b), preferably both the sensor and the conductor are stretched, whereby the conductor can be an electrical conductor and/or an optical conductor.

The functional film structure according to the invention can have any shape, for example a circular, elliptical, square, or rectangular design in plan view.

Curvature

The functional film structure according to the invention has at least one curvature and thus a three-dimensional structure.

The curvature is defined such that the functional film is curved from the x-y plane at at least one position in the z-direction by a value corresponding, for example, to at least 2 times the thickness of the functional film. This value is referred to in the present invention as a curvature “of a height of at least a factor 2”. Other examples of a curvature are a height of at least factor 5, at least factor 10 or at least factor 20. The curved section is protrudedly deformed from the surrounding x-y plane in z-direction preferably by at least 1.0 mm, more preferably by at least 3.0 mm.

The functional film structure according to the invention thus preferably has, in each direction x, y, and z, a value corresponding to at least 2 times, at least 5 times, at least 10 times or at least 20 times the thickness of the functional film.

In the present invention, the parameters x, y, and z are determined as follows: The length in the x-direction and y-direction is obtained for a structure of any shape by fitting it into a rectangular frame of smallest possible area and taking the length of the frame as the x-direction and the width as the y-direction. The height of the structure is the z-direction.

The bend of the curvature in the structure according to the invention is preferably such that at at least one position a tangent can be applied to the structure in such a way that it moves away from the tangent by at least one tenth of this distance, e.g. 1 mm, over a given distance, e.g. 10 mm. This value is referred to in the present invention as a “bend of at least 1/10”. In certain embodiments, the bend so defined is at least 2/10, 5/10 or 10/10.

The forming of the curvature is reflected in the stretching of the film and the components contained therein. A conductor contained within the film, for example an electrical lead, becomes narrower in plan view and/or smaller in cross-sectional area as a result of the stretching. In one embodiment of the invention, the curvature is such that there is a section in the curvature where the same conductor has a reduced cross-sectional area and/or width in plan view compared to the non-curved section or a less curved section. The cross-sectional area and/or width of the conductor is reduced to a value of at most 95%, at most 90%, at most 80% or at most 50% of the cross-sectional area and/or width in the non-curved or a less curved section.

The reduction in the cross-sectional area and/or the width of the conductor is preferably proportional to the extent of the deformation in a given section of curvature. This means that in a strongly bent section of the curvature, the conductor is stretched correspondingly strongly and consequently its width in plan view and/or its cross-sectional area is reduced correspondingly strongly.

The same applies not only to the conductor, but also to the other stretchable elements of the functional film structure such as the sensor.

In addition, more micro-cracks appear in the conductor in the curvature. This means that the number of micro-cracks in the curved section is higher than in the non-curved or less curved section.

Another feature of the curvature is the different structure of the polymers compared to the non-curved section or a less curved section. One difference is, for example, the crystal structure of the polymers in the film substrate and/or in the sensor element.

In the present invention, the term “stretching” or “stretch”, respectively, excludes the mere bending, kinking, or folding of a structure.

Preferably, both the sensor(s) and the conductor(s) connected thereto are stretched in the curvature of the functional film structure.

In one embodiment, the curvature has at least one section where at least one element of the structure, preferably the conductor, is stretched by at least 5%, at least 10%, at least 20% or at least 30% compared to the non-curved section or a less curved section.

In a preferred embodiment, the functional film structure according to the invention has a thickness of at least 0.05 mm, a length and width of at least 1 cm each, a curvature of a height of at least factor 2 and a bend of at least 1/10.

In a further preferred embodiment, the functional film structure according to the invention has a thickness of at least 0.1 mm, a length and width of at least 3 cm each, a curvature of a height of at least factor 4 and a bend of at least 2/10.

In a further embodiment, the functional film structure according to the invention has a thickness of 0.05-10 mm, a length and width of 1-100 cm each, a curvature of a height of at least a factor of 2 and a bend of at least 1/10.

In a further preferred embodiment, the functional film structure according to the invention has a thickness of 0.1-2 mm, a length and width of 3-20 cm each, a curvature of a height of at least factor 4 and a bend of at least 2/10.

The functional film structure according to the invention may have one or more curvatures. The multiple curvatures may be contiguous, or they may be independent of each other so that they are separated by sections where the film substrate is not deformed.

Film Substrate

The film substrate serves as a carrier for the sensor unit. It preferably carries all electrical components of the functional film structure according to the invention.

The film substrate is preferably flexible. The flexibility is defined such that, at room temperature, when a sample piece of the film substrate measuring 3 cm×3 cm is vertically loaded with an object having a mass of 100 g and a contact area of 1 cm² in the direction of loading, an elastic deformation of at least 1 μm, more preferably at least 10 μm and even more preferably at least 50 μm occurs. Examples of preferred elastic deformation ranges are selected from 1 to 1000 μm, 10 to 1000 μm, 50 to 1000 μm, 1 to 500 μm, 10 to 500 μm or 100 to 500 μm.

Suitable film substrates are, for example, carrier films, preferably flexible plastic films, for example made of PI (polyimide), PP (polypropylene), PMMA (polymethyl methacrylate), MOPP (monoaxially stretched film of polypropylene), PE (polyethylene), PPS (polyphenylene sulphide), PEEK (polyetheretherketone), PEK (polyetherketone), PEI (polyethyleneimine), PSU (polysulphone), PAEK (polyaryletherketone), LCP (liquid crystalline polymers), PEN (polyethylene naphthalate), PBT (polybutylene terephthalate), PET (polyethylene terephthalate), PA (polyamide), PC (polycarbonate), COC (cycloolefin copolymer), POM (polyoxymethylene), ABS (acrylonitrile-butadiene-styrene copolymer), PVC (polyvinyl chloride), PTFE (polytetrafluoroethylene), ETFE (ethylenetetrafluoroethylene), PFA (tetrafluoroethylene-perfluoropropylvinylether-fluorocopolymer), MFA (tetrafluoro-methylene-perfluoropropylvinylether-fluorocopolymer), PTFE (polytetrafluoroethylene), PVF (polyvinyl fluoride), PVDF (polyvinylidene fluoride), and EFEP (ethylene-tetrafluoroethylene-hexafluoropropylene-fluoropolymer).

The film substrate can be single-layered or multilayered. A single-layer substrate can be made of one of the mentioned materials, for example PET, PC, PA, PMMA, or PI.

A multilayer film substrate is preferably a film composite. This can, for example, consist of a material combination of the materials listed above.

The film or the film composite has a flat structure. This means that the length in the x-direction and the width in the y-direction are each preferably greater than the thickness in the z-direction by a factor of at least 10, more preferably at least 50, even more preferably at least 100.

EP 2 014 440 A2 describes back-mouldable films or web-shaped laminates consisting of a decorative film and a carrier film. Decorative film and carrier film are joined by a 2-component adhesive system. The decorative film can preferably be made of PMMA, PC, PS, PET or ABS, PP, PU. The thickness of the decorative film is about 6 to 500 μm. The carrier film can be made of the same or different material as the decorative film. The thickness of the carrier film is about 50-800 μm, preferably 150-500 μm.

WO 2016/042414 A2 describes a process for producing a formed circuit carrier in the form of a laminate of adhesion promoter film, possibly adhesive layer, circuit carrier film and purely metallic conducting path.

The production of the film composite can be carried out as follows: The two-dimensional bonding of the film substrate (e.g. PEN) and the carrier film (e.g. ABS) can be carried out by means of a wet lamination process in a roll-to-roll process. In the laminating process, a liquid laminating adhesive is first applied to one of the two films, pre-dried if necessary, and the film thus coated is then bonded to the other film under the action of pressure and/or temperature. For example, water-based or solvent-based laminating adhesives can be used. To increase the durability of the lamination, 2-component laminating adhesives are preferably used. Alternatively, UV-curing laminating adhesives can be used. The laminating adhesive can be applied, for example, by varnishing, by known printing processes such as flexographic printing, gravure printing, offset printing, curtain coating, by spraying, by doctoring and the like.

Sensor or Membrane Keypad

The sensor or the membrane keypad preferably has a flat structure. Preferably, the entire sensor unit has a flat structure.

Flat means that the length in the x-direction and the width in the y-direction are each preferably greater than the thickness in the z-direction by a factor of at least 10, more preferably at least 50, even more preferably at least 100.

The sensor or the membrane keypad is preferably flexible.

Membrane keypads traditionally consist of pushbuttons, which usually establish electrical contact between the surface with printed button symbols and a circuit underneath.

There is a technology that enables intuitive operation of mobile electronic functional film structures (e.g. remote control of industrial robots) by means of pressure-sensitive sensor buttons instead of rotary controls, push buttons and switches. Intuitive operation in this context means that the button generates a signal level that is proportional to the amount of button pressure applied. Thus, the button acts as an analogue button and not as a pure on-off switch. These buttons are based on PyzoFlex® sensor technology. The technology is based on sensors made of special polymers that can detect local pressure and temperature changes with high precision. In this technology, both the pyroelectric effect and the piezoelectric effect are used. A sensor element consists of a polarised ferroelectric polymer layer embedded between two printed electrodes, thus forming a capacitive element. This polymer layer contains ferroelectric crystallites whose electric dipole moment can be aligned by poling in an electric field. After this polarity activation, electrical charges are generated in the sensor layer by the smallest changes in pressure or temperature. These charges flow to the electrodes and can be read out as voltage signals, current signals or charge quantity. The detected signal level is proportional to the strength or speed of the contact. This means that it is not only possible to detect where touching takes place, but also how strong and how fast. The material basis is ferroelectric co-polymers from the PVDF class. With the large-area printable sensors of PyzoFlex® technology, the deformations of the active layer caused by touch are converted into electrical energy via the piezoelectric effect (piezoelectric generators), localised on the operating surface and their pressure force quantified. These sensors can be produced very cost-effectively on flexible surfaces using screen printing processes. Wherever pressure and temperature changes, vibrations, and shock waves occur, piezo generators can convert the mechanical deformations (thickness changes) and pyro generators the temperature differences into electrical energy to act as energy-efficient analogue buttons. The material basis of the PyzoFlex® technology can be a ferroelectric co-polymer (P(VDF-TrFE), polyvinylidene fluoride trifluoroethylene), which is embedded between printed electrode layers and shows strong piezoelectric and pyroelectric activity after electrical poling, has a high chemical robustness, is very UV-resistant and weatherproof, as well as flame-retardant.

Electrically conductive polymers such as PEDOT:PSS (poly(3,4-ethylenedioxythiophene) polystyrene sulphonate) or carbon can be used as electrodes. Poly-3,4-ethylenedioxythiophene (PEDOT) is an electrically conductive polymer based on thiophene.

The PVDF-TrFE sensors can detect pressure differences (typically between a few grams and several kilograms). Depending on the (application-specific) electronics and number of sensors used, these can be scanned at high frequency, enabling fast response times and fluid interaction.

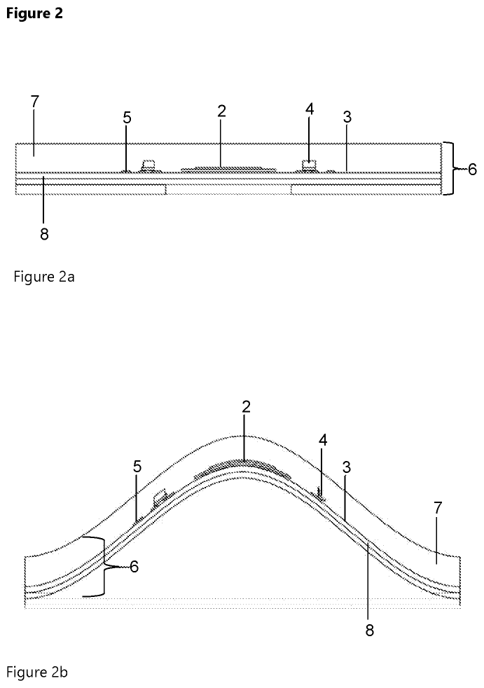

The production of the film sensor buttons can be carried out as follows, for example: The individual layers of the film sensor button (sensor sandwich, conducting paths) and the decorative ink were applied in a structured manner to a pre-cut film composite (e.g. PEN/ABS) by means of an additive screen printing process including intermediate drying through a mask (screen/stencil). The printing sequence is as follows: On the printable PEN side of the film composite, first a PEDOT:PSS layer for the base electrodes (layer thickness 1 μm) is printed, then the ferroelectric sensor layer (layer thickness 10 μm), then the PEDOT:PSS cover electrodes (layer thickness 1 μm), then a carbon layer (layer thickness 1-3 μm) as a conductive diffusion barrier and finally electrical conducting paths (e.g. made of silver) (e.g. with width 2 mm) for contacting to the outside are applied. In addition, a black, and therefore well absorbing, non-conductive decorative ink/contour ink is printed in all sections outside the semi-transparent button section (see FIG. 2), preferably on the back of the film composite (ABS). Bake at 60-65° C. between the printing steps. In general, it must be ensured that all printed materials retain good adhesion to the underlying structure even when heated during the shaping process, and that they have sufficient elasticity for shaping.

In one embodiment, the sensor used in the present invention has a layer structure (sandwich structure) and is thus a layer sensor. It comprises a first electrically conductive layer, a layer of a ferroelectric polymer and a second electrically conductive layer in this order.

The electrically conductive layers can be called electrode layers or electrodes.

The ferroelectric polymer layer can be a, preferably printable, PVDF-TrFE copolymer. Therein, the molar ratio PVDF:TrFE may be, for example, 50:50 to 85:15, preferably 70:30 to 80:20.

The ferroelectric polymer layer may be a, preferably printable, PVDF-TrFE-CFE or PVDF-TrFE-CTFE terpolymer. Therein, the molar ratio PVDF:TRFE:CFE may preferably be 50-75:20-40:5-10, for example 62.6:29.4:8, or PVDF:TRFE:CTFE may preferably be 50-75:20-40:5-10, for example 61.6:29.4:9.

The following abbreviations are used in the present invention: PVDF: polyvinylidene fluoride; TrFE: trifluoroethylene; CFE: chlorofluoroethylene.

The ferroelectric polymer layer can also be a, preferably printable, PVDF-TrFE nanocomposite material. This may contain or consist of inorganic ferroelectric nanoparticles mixed into a PVDF-TrFE matrix. These nanoparticles may be SrTiO₃ (strontium titanate), PbTiO₃ (lead titanate), PbZrTiO₃ (lead zirconium titanate), BaTiO₃ (barium titanate) or BNT-BT (bismuth sodium titanate barium titanate). The nanocomposite material may be included in the ferroelectric polymer layer in a volume fraction (degree of filling) of 5 and 50%, preferably 10 and 35%.

The electrodes may be made of a, preferably printable, conductive material and may contain or consist of PEDOT-PSS, carbon, silver, aluminium, chromium, gold or copper. The electrodes may be made of a metal that can be deposited from the vacuum phase, such as Al, Cu, Au, Ag or chromium.

In a preferred embodiment, both the electrically conductive layers and the ferroelectric layers of the layer sensor are printable.

This layered structure is preferably thermally deformable. The maximum strain during deformation compared to the non-deformed or a less deformed section is at least 5%, at least 10%, at least 20% or at least 30%.

More preferably, the layers of the layer sensor are both printable and thermally deformable.

Even more preferably, both the layers of the layer sensor and the conductors are compressible and thermally deformable. For this purpose, the maximum strain of these elements when deformed compared to the non-deformed or a less deformed section is at least 5%, at least 10%, at least 20% or at least 30%.

Conductor

The conductor connected to the sensor can be any conductor.

It can be an electrical conductor and be in the form of a conducting path. It can also be an optical conductor such as a waveguide for conducting light from an LED to a sensor.

The conductor or the conducting path is preferably printable and/or can be applied by known processes producing partial metal layers, for example vapour deposition, sputtering, roller application processes, spraying, electroplating and the like. Partial metallisation can be achieved by partial metallisation processes, such as partial application of a highly pigmented paint prior to the metallisation process and removal of this paint layer together with the metal layer applied thereon, by using a mask, by etching processes or laser ablation and the like.

In one embodiment, the printed conductive tracks contain or consist of copper or silver. Preferably, they consist essentially of Cu or Ag, that is, they contain at least 90 wt. %, preferably at least 95 wt. % Cu or Ag.

Conductive Adhesive

In the present invention, a conductive adhesive may be used to bond SMD components, for example.

SMD components (SMD =surface-mounted device) are surface-mounted components.

Traditionally, soldering is done with ROHS-compliant solder paste. Adhesion by means of conductive glue is not common.

The conductive adhesive can be selected so that an electrically conductive connection can be made at lower temperatures. Since the curing process of the conductive adhesive is in the range of 120° C. or below, this type of component mounting enables the use of temperature-sensitive substrates, such as PET, PC or PMMA, as well as laminates made from them, and greatly increases the range of applications for electronic components. It should be noted that the adhesive forces with conductive bonding are lower than with conventional soldering, which in turn would restrict the areas of application, especially if there are strong vibrations.

The conductive adhesive application and SMD assembly can be carried out as follows: An isotropic conductive adhesive (MG-8331 S or a modified acrylate adhesive filled with Ag nanoparticles) was applied in a structured manner using a stencil so that only those parts were coated with adhesive that were necessary for contacting the components. The SMD components (LEDs and series resistors) were then positioned in the wet adhesive mass using an automatic pick-and-place machine. The components were electrically connected to the film by curing the adhesive in a drying oven.

The advantage of conductive bonding is the variety of temperature-sensitive substrate materials that can be used due to the lower temperatures.

In the present invention, at least a portion, preferably the entirety, of the electrical components is preferably bonded to the film substrate with a conductive adhesive.

Deformation-Tolerant Lacquer

In conventional assembly with ROHS-compliant solder paste, no deformation-tolerant-protective lacquer is required due to the sufficient adhesive force of the soldering and due to the rigid substrate properties.

The adhesive forces with conductive bonding are lower compared to conventional soldering, which could lead to detachment of the components from the conductive tracks or to an interruption of the electrical contact between component and conductive track over time when the electronic film is mechanically stressed. To counteract this, the components can be coated with an electrically non-conductive protective lacquer after the electrically conductive bonding, which is preferably also absorbed under the component during application. In this way, the mechanical strength between the component and the carrier film is significantly increased, which leads to adhesive forces comparable to conventional soldering. At the same time, the protective lacquer provides both mechanical and electrical protection.

Since the functional films are mechanically flexible and are also deformed three-dimensionally, care must be taken when selecting the protective lacquer to ensure deformation tolerance even in the cured state. Brittleness could lead to hairline cracks and consequently to a break in the electrical contact between the conducting path and the component.

To strengthen the adhesive properties of the SMD components on the film, they can also be fixed locally with a low-viscosity lacquer. The lacquer is applied, for example, using a dispenser, either selectively or over the entire surface by spraying. Due to the high creep properties of the lacquer, it also flows into the space between the underside of the component and the substrate. This maximises the adhesion of the components to the surface.

In the present invention, the electrical components bonded to the film substrate with a conductive adhesive are preferably coated with a lacquer that is preferably deformation tolerant. An example of such a lacquer is NoriCure® MPF.

Adhesive Film

For improved protection of the components during moulding, an adhesive film can be applied to the deformation-tolerant protective lacquer after the film substrate has been loaded. The adhesive film can protect the electronic components from mechanical stresses during forming and back injection and/or serve as a scattering element for homogeneous illumination and/or act as an adhesion promoter for good bonding to the injection moulding material. The adhesive film can preferably consist of a multi-layer structure of hot-melt adhesive (for example based on PA, PE, APAO, EVAC, TPE-E, TPE-U, TPE-A) and scatter film. Afterwards, the unformed functional film can be cut to size on the forming tool, for example with a laser cutter. The adhesive film can be a hot-melt adhesive film.

Hot-melt adhesives are solvent-free products that are more or less solid at room temperature. They are applied to the bonding surface when hot and form a solid bond when they cool. The advantages of a hot-melt adhesive include the fact that it can be used to bond a wide variety of materials, it is therefore also suitable for porous material surfaces and can compensate for unevenness of the bonded surfaces. In addition, the adhesive joint has great elasticity.

In the present invention, an embodiment is preferred in which electrical components are bonded to the film substrate with a conductive adhesive, these components are coated with a preferably deformation-tolerant lacquer, and these components and the lacquer are coated with an adhesive film, preferably a hot-melt adhesive film.

The functional film structure according to the invention thus preferably comprises a film substrate, a conductive adhesive, electrical components, a lacquer and an adhesive film in this order.

In addition to the layer sensors, the functional film structure according to the invention particularly preferably features a film substrate, a conductive adhesive, electrical components, a lacquer and an adhesive film in this order. This layered structure without sensors is referred to as a component mounting structure.

As described above, the sensor in the functional film structure according to the invention is preferably a layered sensor comprising a first electrically conductive layer, a layer of a ferroelectric polymer and a second electrically conductive layer in that order.

A particularly preferred embodiment of the functional film structure according to the invention contains on the film substrate both a component mounting structure comprising a conductive adhesive, electrical components, a lacquer and an adhesive film, in that order, and a layer sensor connected to the layer structure via conductors, comprising a first electrically conductive layer, a layer of a ferroelectric polymer and a second electrically conductive layer, in that order.

The adhesive film is preferably a hot-melt adhesive film.

In one embodiment, the adhesive film or hot-melt adhesive film also covers the layer sensor.

The components contained in the component mounting structure are preferably SMD components.

The sensor unit may also comprise one or more series resistors. These may be printable and contain or consist of conductive materials. A series resistor may be an SMD component and/or may be attached to the film substrate by a conductive adhesive. The attached series resistor may be coated with protective lacquer or fixing lacquer.

In one embodiment, the sensor, the light-emitting element and/or the series resistor is connected to the outside via printed conductors or contacts an electrical element arranged outside.

The functional film structure according to the invention may have a protective film arranged over the electrical components, over the sensor, the light-emitting element and the series resistors, preferably as a hot-melt adhesive film.

It is noted that the component mounting structure on the film substrate described herein may constitute a separate invention, i.e. is independent of the other elements of the functional film structure. That is, an assembly comprising a component mounting structure on a film substrate as described herein having a curvature as defined in this application is a separate invention and could be claimed independently.

This invention is defined as follows:

A functional film structure having a curvature obtainable by a process comprising the steps of:
(a) providing a functional film comprising a film substrate and a component mounting structure thereon having a conductive adhesive, electrical components and a lacquer in that order; and
(b) forming a curvature in the functional film in a section of the component mounting structure, wherein at least the conductive adhesive and the lacquer are stretched.

This functional film structure may further comprise an adhesive film over the component mounting structure for bonding to the film substrate, whereby the adhesive film is also stretched during deformation.

Transparency

The functional film structure according to the invention can have transparent sections. Preferably, the entire functional film structure is transparent.

The transparency of the layered structure is preferably at least 60%, more preferably at least 70%, even more preferably at least 80% and particularly preferably at least 90%. Transparency is defined in the present invention as solar radiation at room temperature penetrating the structure to the extent mentioned. More precisely, transparency can be defined when light of a certain wavelength, for example at the maximum of solar radiation (500 nm), is used.

Lighting

The integration of lighting systems in very flat and thin layers already takes place with so-called light guide plates. Typically, LED light is coupled in laterally at the end faces of an optical waveguide (transparent plastic sheet or film) and transmitted by means of total reflection. At defined positions, the light is coupled out of the light guide through scattering structures distributed in the light guide material, fine surface structures or fine printed patterns, whereby a constant luminance for e.g. the backlighting of operating elements requires an uneven spatial distribution of these patterns. There is also a thin-film waveguide system on film processed by roll-to-roll (R2R), which has a coupling efficiency of 25% for bending radii of 2 mm. A key criterion in this waveguide system is the high-index layer of an inorganic material vaporised in an R2R physical vapour deposition (PVD) process between the core and cladding; this enables waveguiding with low losses and efficient coupling out via the embossed grating.

At least one light-emitting component may be arranged in the functional film structure according to the invention. A number of 1 to 16 is preferred, more preferably 4 to 8. he light-emitting component may be an SMD component. The height of the light-emitting element may be less than 1 mm, preferably less than 300 μm and even more preferably less than 100 μm. It may be an organic LED or purely electroluminescent element.

The thin thickness of the LEDs minimises the mechanical stress on the LEDs during the final deformation of the membrane sensor button.

Preferably, more than one light-emitting element is integrated into the functional film structure, whereby the arrangement of these elements can be symmetrical or asymmetrical with respect to the shape of the at least one sensor.

The distance of the LEDs to the active section of the at least one sensor can be 0.1 cm to 10 cm, preferably 0.2 to 1 cm.

The light of the light-emitting element may be coupled into the sensor button via at least one waveguide. The waveguide can contain at least one laminated POF (plastic optical fibre). POFs are optical waveguides made of plastic that are primarily used for data transmission, but are also used in (indirect) lighting in the form of sidelight fibres.

The waveguide may consist of structures introduced into a preferably transparent, preferably flexible and preferably stretchable polymer material with an increased refractive index compared to the film substrate.

The light is emitted by the LEDs in all directions. Optionally, a light-scattering adhesive film can be applied over the sensor button, the LEDs and the series resistors. This scattering film serves on the one hand to backscatter and homogenise the light in the direction of the sensor button and on the other hand to protect the discrete components (LEDs, resistors). Optionally, an absorbent lacquer can be applied over the LEDs, preferably on the back of the film substrate, to prevent light from passing through at positions outside the sensor button. In this way, a relatively homogeneous, bright and high-contrast sensor button illumination can be realised. The light-emitting element can, for example, be coated with a black, non-transparent and non-conductive decorative paint.

The functional film structure may comprise an array of light-emitting elements.

Manufacturing Process

The functional film structure according to the invention can be manufactured in a process comprising the following steps:
(a) providing a functional film comprising a film substrate and a sensor unit disposed thereon having a sensor and a conductor connected thereto; and
(b) forming a curvature in the functional film in a section at least partially comprising the sensor and the conductor, stretching at least the conductor.

Preferably, step (a) comprises providing the film substrate, equipping the film substrate with the sensor, conductor and other elements, and applying a film to the equipped film substrate to produce the functional film.

According to the invention, the first step is to apply the sensor and the conductor to the film substrate and the second step is to shape the functional film structure. Preferably, the functional film is also equipped with other elements, such as SMD components, and covered with a film in the first step. However, it should be noted that at least one of these further steps can also be carried out after shaping.

The functional film structure according to the invention can be produced in a process in which all electrical, sensory and electro-optical functions are provided on a flat film composite in a first set of process steps and this film composite provided with functions is three-dimensionally deformed in a second set of steps. The first set of steps may include the production of the film composite, the sandwiched sensor, the conducting paths, the placement of SMD components and their fixation, and the production of the entire laminate. The second set of steps may include cutting the composite onto the forming tool and three-dimensional forming.

In one embodiment, the film composite is produced by means of a wet lamination process in a roll-to-roll process.

The layer structure of the sensor button, comprising a base electrode, a ferroelectric layer and a cover electrode, can be produced by screen printing or engraving with intermediate bake-out steps.

The conductive tracks can also be applied by screen printing and a subsequent baking step. In one embodiment, the bake-out temperature is a maximum of 200° C., preferably a maximum of 100° C. Before applying the conductive tracks, a carbon layer can be applied to the contact points between the cover electrode and the conductive track. This carbon layer serves as a diffusion barrier and can be applied by screen printing.

It is important for the production of the functional film structure according to the invention that the process temperature does not exceed a certain value. It is preferably below 200° C., more preferably below 150° C., so that the properties of the sensor materials can be maintained and the film does not deform.

The application of a conductive adhesive, which is used, for example, to attach the SMD components, can be carried out by means of stencil printing. The adhesive can be an isotropic conductive adhesive. It can be applied to Ag contact pads. The film obtained after a printing process can be called printed film.

Said other elements that can be applied in step (a) can be SMD components.

Equipping with SMD components can be carried out in an automatic or semi-automatic pick-and-place machine with a subsequent bake-out step of the adhesive. The film obtained after an equipping process can be called an equipped film. The SMD components can be protected and fixed in a dispenser with fixing lacquer after equipping.

The application of a film referred to in step (a) serves to protect the components on the film substrate. This application can be a thermal lamination with a hot-melt adhesive film.

In one embodiment, the entire unformed functional film is covered again by thermal lamination with a light-scattering hot-melt adhesive film, thereby protecting it. The film obtained after a lamination process can be called a laminated film.

The functional film structure according to the invention may be referred to as an unformed functional film or simply as a functional film before shaping, i.e. before forming the curvature.

After the printing steps, equipping and fixing of the components, the electrical activation (=poling) of the ferroelectric layer can take place. In this process, the dipoles of the nanocrystallites in the ferroelectric layer are aligned by poling in a high-voltage field with typical poling field strengths of 80 to 200 MV/m, which creates a macroscopic polarisation normal to the electrode surfaces and, when the sensor button is mechanically or thermally activated, charges are generated by the piezo- or pyroelectric effect. After the poling, the remanent polarisation can be determined by evaluating the hysteresis curves, which is used as a quality criterion for the functionality of each sensor pixel.

As mentioned above, in the process according to the invention, the first step can be the application of the sensor and the conductor to the film substrate, as well as the equipping with other elements, the lamination and other additional steps.

However, at least one of these additional steps can also be carried out after shaping. For example, the equipping with the other elements or the protective lamination can be done after the shaping. Other examples include applying an absorbent lacquer or decorative paint and applying an injection moulding to the back of the structure. Performing these steps after deformation may have the advantage of allowing the use of materials that do not have the required ductility during deformation. In this way, the range of materials that can be used can be expanded.

The functional film, which is preferably ready printed, equipped, polarised, laminated and cut to size, can be shaped three-dimensionally against a tool in a high-pressure forming process. The shaping process can take place under a pressure of up to 160 bar and at a temperature of 140° C. and lasts approx. 1 min, forming a functional film structure. The maximum elongation during deformation compared to the non-deformed or a less deformed section is at least 5%, at least 10%, at least 20% or at least 30%.

The unshaped functional film, which may be printed, equipped, and laminated, can be cut to size on a shaping tool. The three-dimensional deformation of the functional film, which may be printed, equipped, laminated, and cut to size, can be carried out by a high-pressure forming process against a suitable tool. In this process, the maximum temperature is preferably 300° C., more preferably 200° C. and the maximum pressure is preferably 400 bar, more preferably 300 bar. The three-dimensional deformation of the functional film can be carried out by a deep-drawing process against a suitable tool, so that the functional film structure according to the invention is obtained.

After forming, an injection moulding can be applied to the back of the functional film structure. Thus, the component can be given even more dimensional stability. However, care must be taken to ensure that sufficient mechanical flexibility remains below the sections of the buttons. This can be achieved, for example, through the targeted inclusion of air bubbles.

### EXAMPLES

The present invention is further illustrated by the following examples.

### Example 1

Sensor buttons having diameters of 10 mm, 15 mm and 20 mm were provided on a thermoplastic deformable film substrate (PMMA film, thickness: 175 μm). The round buttons were made of sufficiently transparent materials in sandwich construction having a base electrode layer, a ferroelectric sensor layer and a cover electrode layer. The electrical contact to the outside was made via ring-shaped conductor paths. For backlighting, LED light sources were mounted outside the actual sensing section. The integration of the LEDs directly next to the sensor section required a very small design of the LEDs. These were provided using pico-LEDs (SMD components) with very small dimensions (1 mm×0.6 mm) and a low thickness of 0.2 mm. The illumination of the sensor buttons was examined in advance using optical simulations with a commercial ray-tracing tool (OpticStudio). Based on the simulations, a sufficient number of pico-LEDs and an equivalent number of series resistors were placed outside the button touch section.

The production was carried out as follows: First the pressure-sensitive sections of the sensor buttons were printed in sandwich construction, then the series resistors (1 series resistor per LED) and finally the conducting paths were printed directly onto the PMMA film. The base electrodes of the sensor button made of PEDOT:PSS were applied by screen printing (layer thickness of the electrodes approx. 1 μm) and then baked out at 100° C. to remove any solvents contained. PEDOT:PSS forms electrodes that are highly conductive, semi-transparent and sufficiently smooth for further printing. Afterwards, the ferroelectric sensor layer made of PVDF-TrFE copolymer (P(VDF:TrFE)=70:30 with a layer thickness of approx. 10 μm) was also applied by screen printing, whereby this layer completely overlapped the base electrodes. The layer was then baked at 100 degrees to remove the solvent (e.g. modified y-butyrolactone). By means of screen printing, the conductive tracks of silver (width approx. 1 mm) were printed to enable the electrical connection to the outside, namely to the voltage supply of the LEDs and to an evaluation electronics (e.g. transimpedance amplifier, charge amplifier) for the amplification and processing of the signals generated by the finger pressure. Furthermore, cover electrodes made of PEDOT-PSS (layer thickness of the electrodes approx. 1 μm) were screen-printed and baked (100° C.), whereby their lateral expansion is preferably somewhat smaller than that of the base electrodes. After screen printing the carbon series resistors (and baking at 100° C. for 15 min), the pico-LEDs were conductively glued to the film by hand as the last manufacturing step, using a modified acrylate adhesive filled with Ag nanoparticles.

Subsequently, the semi-crystalline ferroelectric polymer layer was polarised in an electric field. The electrical poling step was carried out using hysteresis poling with typical poling field strengths of 80 to 200 MV/m.

After integration of all functionalities on the PMMA film (sensor button and illumination) and electrical poling, the functional film was shaped three-dimensionally in a vacuum- and temperature-assisted process. The three-dimensional shape corresponded to a spherical calotte with a maximum elongation of approx. 40%.

### Example 2

This example describes a method of manufacturing a backlit pressure or temperature sensitive film sensor button having a three-dimensional shape (see FIG. 2).

First, a film composite was produced. The two-dimensional bonding of the functional film (e.g. PEN) and the carrier film (e.g. ABS) was carried out by means of a wet lamination process in a roll-to-roll procedure. In the laminating process, a liquid laminating adhesive was first applied to one of the two films, pre-dried and the film thus coated was then bonded to the other film under the effect of pressure and/or temperature.

Then, the film sensor button was produced. The individual layers of the film sensor button (sensor sandwich, conducting paths) and the decorative ink were applied in a structured manner to a pre-cut film composite (e.g. PEN/ABS) using an additive screen printing process including intermediate drying through a mask (screen/template). The printing sequence was as follows: On the printable PEN side of the film composite, first a PEDOT:PSS layer for the base electrodes (layer thickness 1 μm) and then the ferroelectric sensor layer (layer thickness 10 μm) were printed, then the PEDOT:PSS cover electrodes (layer thickness 1 μm), then a carbon layer (layer thickness 1-3 μm) as a conductive diffusion barrier and finally electrical conducting paths (e.g. made of silver) (width 2 mm) for external contacting were applied. In addition, a black and therefore well absorbing, non-conductive decorative ink/contour ink was printed in all sections outside the semi-transparent button section (see FIG. 2). Baking was carried out at 60-65° C. between the printing steps.

Afterwards, the adhesive was applied and the SMD assembly was carried out. An isotropic conductive adhesive (MG-8331S or modified acrylate adhesive filled with Ag nanoparticles) was applied in a structured manner using a template. The SMD components (LEDs and series resistors) were then positioned in the wet adhesive mass using an automatic pick-and-place machine. The components were electrically connected to the film by curing the adhesive in a drying oven at 100° C. with a dwell time of 15 minutes.

To strengthen the adhesion properties of the SMD components on the film, they were additionally fixed locally with a low-viscosity lacquer.

Afterwards, the electrical activation (=polarisation) of the ferroelectric layer of the sandwich sensor button was carried out.

After poling, a hot-melt adhesive film (hot-melt adhesives based on PA, PE, APAO, EVAC, TPE-E, TPE-U, TPE-A) was laminated onto the upper side of the film. Afterwards, a laser cutter was used to cut the functional films onto the forming tool.

The cut functional film was deformed three-dimensionally against a tool in a high-pressure shaping process. The deformation process took place under a pressure of up to 160 bar and at a temperature of 140° C. and lasted approx. 1 min. The maximum elongation during deformation was approx. 65%.

### LIST OF REFERENCE SIGNS

1 Film substrate

2 Sensor sandwich

3 Conducting path(s)

4 LED

5 Series resistor

6 Film composite

7 Scattering layer

8 Contour lacquer

What is claimed is:

1. A functional film structure having a curvature and being obtainable by a process comprising the steps of:
(a) providing a functional film comprising a film substrate and a sensor unit disposed thereon, the sensor unit having a sensor and a conductor connected thereto, the sensor responding to at least one change selected from pressure and temperature change, wherein the sensor is a layered sensor comprising, in the indicated order, a first electrically conductive layer, a layer of a ferroelectric polymer and a second electrically conductive layer; and
(b) forming the curvature in the functional film in a section at least partially comprising the sensor and the conductor, thereby stretching the conductor and the sensor.

2. The functional film structure to claim 1, wherein the ferroelectric polymer layer, the electrically conductive layers and the conductor are printable.

3. The functional film structure according to claim 1, wherein the section containing the sensor is thicker than the section adjacent thereto.

4. The functional film structure according to claim 1, which is self-supporting.

5. The functional film structure according to claim 1, wherein the curvature contains a section being stretched by at least 20% in comparison to the non-curved section.

6. The functional film structure according to claim 1, wherein a component mounting structure comprising, in the indicated order, a conductive adhesive, electrical components and a lacquer is applied to the film substrate.

7. The functional film structure according to claim 6, comprising an adhesive film over the component mounting structure or the component mounting structure and the layer sensor for bonding to the film substrate.

8. The functional film structure according to claim 1, comprising a light-emitting element that is coupled to the sensor via a waveguide such that the light-emitting element causes the sensor to illuminate.

9. A functional film structure having a functional film comprising a film substrate and a sensor unit disposed thereon, the sensor unit having a sensor and a conductor connected thereto, the sensor responding to at least one change selected from pressure and temperature change, wherein the functional film further comprises a curvature in a section at least partially comprising the sensor and the conductor, the conductor and the sensor being stretched.

10. A method of manufacturing a functional film structure, comprising the steps of:
(a) providing a functional film comprising a film substrate and a sensor unit disposed thereon, the sensor unit having a sensor and a conductor connected thereto; and
(b) forming a curvature in the functional film in a section at least partially comprising the sensor and the conductor, thereby stretching the conductor and the sensor.

11. The method according to claim 10, wherein step (a) comprises providing the film substrate, equipping the film substrate with the sensor, the conductor and other elements, and applying a film to the equipped film substrate to produce the functional film.

12. The method according to claim 10, wherein the sensor has a layered structure, the other elements comprise SMD components and the application of the film to the equipped film substrate is a thermal lamination with a hot-melt adhesive film.

13. The method according to claim 11, wherein the production of the layer structure of the sensor is carried out by means of screen printing or engraving printing with intermediate baking steps and/or the conductor is applied by means of screen printing and a subsequent baking step.

14. The process according to claim 10, wherein step (b) is performed by a high-pressure forming process or a deep-drawing process against a suitable tool.
